(19) United States
(12) Patent Application Publication
(10) Pub. No.: US 2013/0258794 A1
(43) Pub. Date: Oct. 3, 2013

(54) MEMORY DEVICE HAVING CONTROL CIRCUITRY FOR SENSE AMPLIFIER REACTION TIME TRACKING

(71) Applicants: Shailendra Sharad, Bangalore (IN); Manish Umedlal Patel, Bangalore (IN); Setti Shanmukheswara Rao, Bangalore (IN)

(72) Inventors: Shailendra Sharad, Bangalore (IN); Manish Umedlal Patel, Bangalore (IN); Setti Shanmukheswara Rao, Bangalore (IN)

(73) Assignee: LSI Corporation, Milpitas, CA (US)

(21) Appl. No.: 13/433,637

(22) Filed: Mar. 29, 2012

(51) Int. Cl. G11C 7/06

(52) U.S. Cl. 365/205

(57) ABSTRACT

A memory device includes a memory array comprising a plurality of memory cells arranged in rows and columns, and sensing circuitry coupled to the memory array. The sensing circuitry comprises a plurality of output sense amplifiers configured to sense stored data associated with respective columns of the memory array, and sense amplifier control circuitry configured to generate a sense amplifier control signal for application to control inputs of respective ones of the output sense amplifiers. The sense amplifier control circuitry comprises reaction time tracking circuitry including at least one dummy sense amplifier configured to track reaction time of one or more of the output sense amplifiers, with the sense amplifier control signal being generated at least in part responsive to an output signal of the dummy sense amplifier.

### BACKGROUND

A semiconductor memory device typically includes an array of memory cells arranged in rows and columns, with each memory cell configured to store a data bit. The memory cells within a given row of the array are coupled to a common wordline, while the memory cells within a given column of the array are coupled to a common bitline. Thus, the array includes a memory cell at each point where a wordline intersects with a bitline.

In a semiconductor memory device of the type described above, data may be written to or read from the memory cells of the array using a memory cycle that is divided into a precharge phase and an active phase, with the precharge phase being used to precharge the bitlines to a precharge voltage, and the active phase being used to read or write one or more memory cells of the array. Reading a given memory cell generally comprises transferring data stored within that cell to its corresponding bitline, and writing a given memory cell generally comprises transferring data into that cell from its corresponding bitline.

Conventional approaches to reading data from a memory cell include the use of differential sense amplifiers. In a typical conventional arrangement, sense amplifiers are associated with respective columns of the memory array. For each read memory cycle, the sense amplifier is turned on in order to sense data on a corresponding bitline, and then turned off once the sensed data is latched at the sense amplifier output. The sense amplifier is turned on and off responsive to respective logic states of a sense amplifier enable signal. The turning on and turning off of the sense amplifier is also referred to as enabling and disabling the sense amplifier. The use of differential sense amplifiers generally provides faster sensing with lower dynamic power consumption than single-ended sensing arrangements.

However, controlling the timing of the transitions in the sense amplifier enable signal can be problematic, particularly for high-speed read operations. For example, in conventional arrangements, the sense amplifier enable signal may be provided by a sense latch, with the sense latch being set and reset in order to turn on and turn off the sense amplifiers. More particularly, the sense latch may be reset responsive to a pulse of a sense off signal that corresponds to a delayed and inverted version of the sense amplifier enable signal, as fed back to the sense latch from the sense amplifiers. It can be very difficult to accurately control the delay of the sense off signal, particularly over process, voltage and temperature (PVT) variations for high-speed read operations. As a result, read memory cycle time is increased, thereby degrading memory access time performance.

### SUMMARY

Illustrative embodiments of the present invention provide a memory device comprising sensing circuitry in which one or more dummy sense amplifiers are configured to track reaction time of actual sense amplifiers. Output signals from the dummy sense amplifiers are processed to generate a sense amplifier control signal for disabling the actual sense amplifiers. This allows more accurate control of the sense amplifiers over PVT variations, thereby facilitating high-speed read operations.

In one embodiment, a memory device includes a memory array comprising a plurality of memory cells arranged in rows and columns, and sensing circuitry coupled to the memory array. The sensing circuitry comprises a plurality of output sense amplifiers configured to sense stored data associated with respective columns of the memory array, and sense amplifier control circuitry configured to generate a sense amplifier control signal for application to control inputs of respective ones of the output sense amplifiers. The sense amplifier control circuitry comprises reaction time tracking circuitry including at least one dummy sense amplifier configured to track reaction time of one or more of the output sense amplifiers, with the sense amplifier control signal being generated at least in part responsive to an output signal of the dummy sense amplifier.

By way of example, the sense amplifier control circuitry may further comprise a sense latch having a reset input coupled to an output of the dummy sense amplifier and an output coupled to the control inputs of the output sense amplifiers. A set input of the sense latch and a data input of the dummy sense amplifier may each be coupled to a self-time bitline of a dummy column of the memory device.

A given dummy sense amplifier of the reaction time tracking circuitry may be configured for sensing of the self-time bitline by coupling of a first internal node of the dummy sense amplifier to the self-time bitline via at least one pass gate transistor and coupling of a second internal node of the dummy sense amplifier to an upper voltage supply line. In such an arrangement, the pass gate transistor is configured to ensure that a minimum differential voltage will appear between the first and second internal nodes of the dummy sense amplifier at a time when the dummy sense amplifier is enabled, which improves the accuracy of the reaction time tracking.

One or more of the illustrative embodiments can provide a memory device that exhibits shorter read memory cycles and lower power consumption, as well as improved overall operating performance, relative to conventional devices.

A memory device in accordance with embodiments of the invention may be implemented, for example, as a stand-alone memory device, such as a packaged integrated circuit, or as an embedded memory in a microprocessor or other processing device.

### BRIEF DESCRIPTION OF THE DRAWINGS

FIG. 1 shows a semiconductor memory device comprising a memory array having a plurality of memory cells and incorporating sense amplifier control circuitry that includes one or more dummy sense amplifiers for sense amplifier reaction time tracking in an illustrative embodiment of the invention.

FIGS. 2 and 3 show more detailed views of the FIG. 1 memory device in respective illustrative embodiments.

FIG. 4 is a block diagram of a processing device which incorporates the memory device of FIG. 1.

FIG. 5 is a block diagram of a processor integrated circuit which incorporates the memory device of FIG. 1 as an embedded memory.

### DETAILED DESCRIPTION

Embodiments of the invention will be illustrated herein in conjunction with exemplary semiconductor memory devices and associated sensing circuitry. It should be understood, however, that embodiments of the invention are more generally applicable to any semiconductor memory device in which improvements in sensing circuitry performance are desired, and may be implemented using circuitry other than that specifically shown and described in conjunction with the illustrative embodiments.

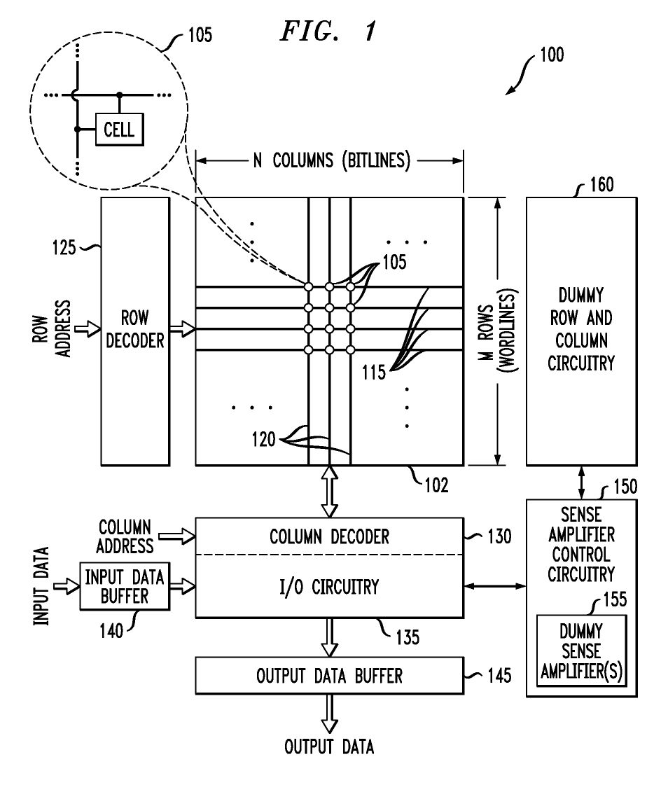

FIG. 1 shows a simplified diagram of a memory device 100 in accordance with an illustrative embodiment of the invention. The memory device 100 comprises a memory array 102. The memory array 102 comprises a plurality of memory cells 105 each configured to store a single bit of data. Each cell 105 is coupled to a corresponding row or wordline 115 and column or bitline 120. The memory array therefore includes a memory cell at each point where a wordline intersects with a bitline. The memory cells of the memory array are illustratively arranged in N columns and M rows. The values selected for N and M in a given implementation will generally depend upon on the data storage requirements of the application in which the memory device is utilized.

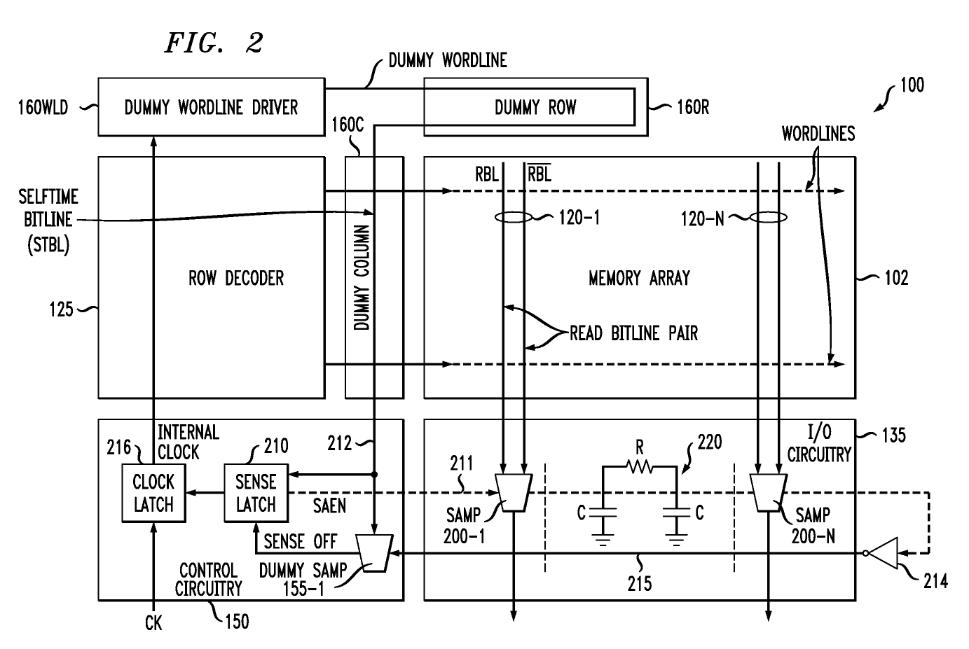

Particular ones of the memory cells 105 of the memory array 102 can be activated for writing data thereto or reading data therefrom by application of appropriate row and column addresses to respective row decoder 125 and column decoder 130. Other elements of the memory device 100 include input/output (I/O) circuitry 135, an input data buffer 140 and an output data buffer 145. The I/O circuitry 135 in the present embodiment is assumed by way of example to comprise sensing circuitry, as will be described in greater detail in conjunction with FIGS. 2 and 3. The operation of other memory device elements such as row decoder 125, column decoder 130, and buffers 140, 145 is well understood in the art and will not be described in detail herein.

Although memory array 102 is identified in FIG. 1 as comprising the cells 105 and their associated wordlines and bitlines 115 and 120, the term “memory array” as used herein is intended to be more broadly construed, and may encompass one or more associated elements such as the row and column decoders 125 and 130, the I/O circuitry 135, or the input and output data buffers 140 and 145, or portions thereof.

Also, the wordlines 115 and bitlines 120, although shown as respective single lines in FIG. 1, may each comprise separate read and write wordlines or bitlines. A given such read or write wordline or bitline may comprise a pair of differential lines, such as a read wordline RWL and its complement R̅W̅L̅, and a read bitline RBL and its complement R̅B̅L̅. Examples of read bitline pairs can be seen in FIG. 2.

The memory device 100 in one or more of the illustrative embodiments may be assumed to comprise a static random access memory (SRAM) device. However, as indicated previously, the disclosed sensing circuitry can be adapted in a straightforward manner for use with other types of memory devices, including, for example, dynamic random access memory (DRAM), electrically erasable programmable ROM (EEPROM), magnetic RAM (MRAM), ferroelectric RAM (FRAM), phase-change RAM (PC-RAM), etc. Also, other types of memory cell configurations may be used. For example, the memory cells 105 in the memory array 102 could be multi-level cells each configured to store more than one bit of data. Embodiments of the invention are therefore not limited in terms of the particular storage or access mechanism utilized in the memory device.

The present embodiment of memory device 100 is configured to avoid one or more of the drawbacks of conventional practice through the use of sense amplifier control circuitry 150 that illustratively comprises one or more dummy sense amplifiers 155 configured to track reaction time of actual sense amplifiers in the I/O circuitry 135. The sense amplifier control circuitry 150 is coupled to dummy row and column circuitry 160 that is associated with the memory array 102, but may be at least partially incorporated into the memory array in other embodiments. As will be described, output signals from the dummy sense amplifiers are processed to generate a sense amplifier control signal for disabling the actual sense amplifiers. This allows more accurate control of the sense amplifiers over PVT variations, thereby facilitating high-speed read operations.

The I/O circuitry 135 and the sense amplifier control circuitry 150 are one example of what is more generally referred to herein as “sensing circuitry.” Such sensing circuitry may additionally encompass other elements of the memory device 100, such as portions of the dummy row and column circuitry 160. The term “sensing circuitry” as used herein is therefore intended to be broadly construed.

The memory device 100 as illustrated in FIG. 1 may include other elements in addition to or in place of those specifically shown, including one or more elements of a type commonly found in a conventional implementation of such a memory device. These and other conventional elements, being well understood by those skilled in the art, are not described in detail herein. It should also be understood that the particular arrangement of elements shown in FIG. 1 is presented by way of illustrative example only. Those skilled in the art will recognize that a wide variety of other memory device configurations may be used in implementing embodiments of the invention.

Referring now to FIG. 2, a more detailed view of the FIG. 1 memory device 100 is shown. In this embodiment, the memory array 102 includes N pairs of read bitlines 120-1 through 120-N, with one such pair associated with each column of the memory array, and each pair comprising a read bitline RBL and its complement RBL. The dummy row and column circuitry 160 in this embodiment more particularly comprises a dummy wordline driver 160WLD, a dummy row 160R and a dummy column 160C. The dummy column 160C is coupled between the row decoder 125 and the memory array 102. The dummy write line driver 160WLD is coupled to an internal clock line that passes through the row decoder 125, and is also coupled via a dummy wordline to the dummy row 160R.

The I/O circuitry 135 comprises a plurality of output sense amplifiers 200-1 through 200-N that are configured to sense stored data associated with respective columns of the memory array 102 in conjunction with read operations directed to the array. Each of the output sense amplifiers 200 is configured to sense data associated with a corresponding one of the read bitline pairs 120. Thus, for example, output sense amplifier 200-1 is coupled to the read bitline RBL and its complement R̅B̅L̅ of read bitline pair 120-1. The output sense amplifiers 200 are therefore implemented as differential sense amplifiers.

The sense amplifier control circuitry 150 is configured to generate a sense amplifier control signal for application to control inputs of respective ones of the output sense amplifiers 200. The sense amplifier control circuitry comprises at least one dummy sense amplifier 155-1 configured to track reaction time of one or more of the output sense amplifiers 200. The sense amplifier control signal is generated at least in part responsive to an output signal of the dummy sense amplifier 155-1.

In this embodiment, the sense amplifier control signal more particularly comprises a sense amplifier enable (SAEN) signal which is supplied from a sense latch 210. The SAEN signal in the present embodiment is assumed to transition from a logic “0” level to a logic “1” level in order to enable the sense output amplifiers 200, although other types of signals may be used in other embodiments.

The dummy sense amplifier 155-1 is part of what is referred to herein as “reaction time tracking circuitry” of the sense amplifier control circuitry 150. The dummy sense amplifier is differential sense amplifier configured in substantially the same manner as each of the output sense amplifiers 200, and therefore tracks the reaction time of those output sense amplifiers to applied signals, including the SAEN signal as well as the differential signals that are sensed by the output sense amplifiers.

The above-noted output signal of the dummy sense amplifier 155-1 in the present embodiment comprises a sense off signal. The sense off signal is applied to a reset input of the sense latch 210, which may be an active low reset input, such that a logic “0” level of the sense off signal is operative to reset the sense latch 210. The output of the sense latch provides the SAEN signal via signal line 211 to the control inputs of respective ones of the output sense amplifiers 200. The output signal from the dummy sense amplifier is therefore used to reset the sense latch 210 so as to control the disabling of the sense amplifiers 200.

The dummy sense amplifier 155-1 and a set input of the sense latch 210 are both coupled to a self-time bitline (STBL) 212 of the dummy column 160C. Although not expressly illustrated in the FIG. 2 embodiment, the set input of the sense latch is assumed to be coupled to the self-time bitline 212 via an inverter.

As will be described in greater detail below in conjunction with FIG. 3, the dummy sense amplifier 155-1 is configured for sensing of the self-time bitline 212 by coupling of a first internal node of the dummy sense amplifier to the self-time bitline via at least one pass gate transistor and coupling of a second internal node of the dummy sense amplifier to an upper voltage supply line.

The dummy sense amplifier 155-1 has a control input adapted to receive a feedback signal generated from the SAEN signal applied to the control inputs of the output sense amplifiers 200. More particularly, an inverter 214 has an input adapted to receive the SAEN signal and an output providing the corresponding feedback signal for application to the control input of the dummy sense amplifier 155-1 via signal line 215.

The sense amplifier control circuitry 150 further includes a clock latch 216 that receives an input clock signal. The clock latch 216 provides at its output an internal clock signal that drives the row decoder 125. The clock latch 216 also has an input coupled to an output of the sense latch as shown.

The resistor-capacitor (RC) circuitry 220 shown in I/O circuitry 135 models the horizontal RC delay experienced by the SAEN signal as it traverses the set of N output sense amplifiers 200. It is not actual circuitry present in the memory device, but instead illustrates the delay impact of the horizontal signal path traversed by the SAEN signal.

The sense amplifier control circuitry 150 in the present embodiment provides efficient tracking of the reaction time of the output sense amplifiers 200. The dummy sense amplifier 155-1 receives its differential inputs from the self-time bitline 212. This self-time bitline also triggers the SAEN signal that is generated in sense latch 210 and applied via signal line 211 to the control inputs of the output sense amplifiers 200. As noted above, the SAEN signal is also fed back in inverted form to the control input of the dummy sense amplifier 155-1 via inverter 214 and signal line 215.

The dummy sense amplifier 155-1 amplifies a differential signal between the self-time bitline 212 and an upper voltage supply line in substantially the same way that the output sense amplifiers 200 amplify the differential signals between their respective bitline pairs 120. The sense off signal generated by the dummy sense amplifier 155-1 resets the sense latch 210 and therefore causes the SAEN signal to transition from its logic “1” level to its logic “0” level, which disables the output sense amplifiers 200. As a result, the turn-on duration of the output sense amplifiers is more accurately controlled over PVT variations, thereby facilitating high-speed read operations in the memory device 100.

In the FIG. 2 embodiment, only a single dummy sense amplifier 155-1 is shown. However, other embodiments of the invention include more than one dummy sense amplifier. An illustrative embodiment of this type will now be described in greater detail with reference to FIG. 3.

The circuitry shown in FIG. 3 includes sense amplifier control circuitry 150′ which operates in a similar manner to the sense amplifier control circuitry 150 previously described in conjunction with FIG. 2, but includes two dummy sense amplifiers 155-1 and 155-2. Again, each of these dummy sense amplifiers comprises a differential sense amplifier substantially matched to the output sense amplifiers 200, only one of which is explicitly shown in the FIG. 3 diagram for simplicity of illustration. The sense latch 210 in this embodiment includes a latch 300 and a buffer 302. An output of the buffer provides the SAEN signal to the output sense amplifiers 200. The SAEN signal is fed back in inverted form via inverter 214 and feedback signal line 308 to control inputs of the dummy sense amplifiers 155-1 and 155-2 in reaction time tracking circuitry 310.

Output signals from respective ones of the dummy sense amplifiers 155-1 and 155-2 are applied to logic circuitry that generates the sense off signal for application to a reset input of the latch 300 of sense latch 210. The logic circuitry in this embodiment comprises a NAND gate 312 having first and second inputs adapted to receive first and second output signals from the first and second dummy sense amplifiers, respectively, and an output providing the sense off signal for application to the reset input of the latch 300 of sense latch 210. The reset input is assumed to be an active low input in the present embodiment, but other latch signaling configurations could be used.

Each of the dummy sense amplifiers 155-1 and 155-2 is configured to sense differential signals between the self-time bitline 212 and the upper voltage supply VDD. Thus, first sensing inputs 316-1 and 316-2 of respective dummy sense amplifiers 155-1 and 155-2 are coupled via pass gate circuitry to the self-time bitline 212, and second sensing inputs 317-1 and 317-2 of respective dummy sense amplifiers 155-1 and 155-2 are coupled to VDD. The pass gate circuitry will be described in greater detail below.

As indicated previously, the dummy sense amplifiers 155 of reaction time tracking circuitry 310 are configured to track reaction time of the output sense amplifiers 200 to both the SAEN signal and the differential signals applied via their respective bitline pairs. Such an arrangement provides improved tracking over PVT variations, particularly for high-speed read operations.

Dashed inset 320 in FIG. 3 shows output sense amplifier 200-1 in greater detail. It is assumed that the other output sense amplifiers 200 and the dummy sense amplifiers 155 are each configured in a similar manner. The sense amplifier 200-1 in the present embodiment is a differential sense amplifier having first and second internal nodes denoted D and DN, which are coupled to RBL and its complement, respectively, in the read bitline pair 120-1, via pass gate transistors.

The sense amplifier 200-1 as shown comprises pairs of cross-coupled transistors having their gates coupled to respective ones of the first and second internal nodes D and DN. More particularly, in this embodiment the output sense amplifier 200-1 comprises a pair of cross-coupled p-type metal-oxide-semiconductor (PMOS) transistors P1 and P2, with the gates of P2 and P1 being coupled to respective ones of the first and second internal nodes D and DN, and a pair of cross-coupled n-type metal-oxide-semiconductor (NMOS) transistors N1 and N2, with the gates of N2 and N1 being coupled to respective ones of the first and second internal nodes D and DN.

The sense amplifier 200-1 also includes control circuitry illustratively comprising NMOS transistor N3. The transistor N3 is configured to enable the sense amplifier to sense data at the first and second internal nodes D and DN responsive to a sense enable (SEN) signal. The SEN signal is generated from the SAEN signal via a series pair of inverters, including inverter 321, and is considered a type of sense amplifier control signal as that term is used herein. The other inverter of the series pair of inverters is omitted from the figure. Thus, the logic levels of the SEN signal track those of the SAEN signal.

In this embodiment, the gate of N3 is adapted to receive the SEN signal from inverter 321, its drain is coupled to the sources of N1 and N2, and its source is coupled to a lower voltage supply line, illustratively VSS. A variety of other types of control circuitry may be used to control enabling of the sense amplifier 200-1 in other embodiments, as will be readily apparent to those skilled in the art. Also, in other embodiments the SAEN signal may be directly applied to the sense amplifier, rather than applied after multiple inverter delays as in the case of the above-described SEN signal. The gate of transistor N3 is one example of what is more generally referred to herein as a “control input” of a sense amplifier. Other types of control inputs may be used to enable or disable a given sense amplifier in other embodiments.

Referring again to the pairs of cross-coupled transistors P1-P2 and N1-N2 in the sense amplifier 200-1, the source of P1 is coupled to the upper voltage supply line, illustratively VDD, and its drain is coupled to the first internal node D. The source of P2 is coupled to VDD, and its drain is coupled to the second internal node DN. The source of N1 is coupled to VSS, via the control circuitry transistor N3, and its drain is coupled to the first internal node D. The source of N2 is coupled to VSS via the control circuitry transistor N3, and its drain is coupled to the second internal node DN.

The first and second internal nodes D and DN of the sense amplifier 120-1 are coupled to RBL and its complement, respectively, in the read bitline pair 120-1, via respective PMOS pass gate transistors P3 and P4. The pass gate transistors P3 and P4 may each be controlled by the same SEN signal that is applied to the gate of N3. Alternatively, a separate control signal may be provided to these pass gate transistors. For example, a SENP control signal may be applied to the gate terminals of P3 and P4. As a more particular example, the SENP control signal may be configured to have a falling edge that is two inverter delays after a corresponding falling edge of SAEN and a rising edge that is four inverter delays from a corresponding rising edge of SAEN, such that there is a short period of overlap time after transistor N3 turns on but before the pass gate transistors P3 and P4 are turned off.

It is to be appreciated that the particular sense amplifier configuration shown at 320 in FIG. 3 is presented by way of illustrative example only, and other embodiments may use other types and arrangements of sensing circuitry. For example, a given sense amplifier in another embodiment may include an isolation buffer and an output latch. Although the isolation buffer 306 is considered part of the sense amplifier 302 in the present embodiment, in other embodiments this buffer may be considered part of the latch circuit, or part of another memory device component. The term “sense amplifier” as used herein is therefore intended to be broadly construed, and should not be viewed as being limited to the particular arrangements shown and described in conjunction with the illustrative embodiments.

As noted above, the set input of the sense latch 210 is coupled to the self-time bitline 212 via an inverter, illustratively shown in FIG. 3 as inverter 330 comprising PMOS transistor P5 and NMOS transistor N5.

Referring now once again to the reaction time tracking circuitry 310 of FIG. 3, the manner in which the dummy sense amplifiers 155-1 and 155-2 are coupled to the self-time bitline 212 will now be described in greater detail. In the present embodiment, the sensing input 316-1 of dummy sense amplifier 155-1 is coupled to the self-time bitline 212 via pass gate circuitry comprising PMOS transistors P10, P11 and P12 arranged as shown. Similarly, the sensing input 316-2 of dummy sense amplifier 155-2 is coupled to the self-time bitline 212 via pass gate circuitry comprising PMOS transistors P13, P14 and P15 arranged as shown. The gates of PMOS transistors P11, P12, P14 and P15 are coupled together, while the gates of P10 and P13 are both coupled to a pass gate control signal. The pass gate control signal in the present embodiment is a self-time wordline (STWL) generated by the dummy wordline driver 160WLD using the internal clock supplied by clock latch 216.

Although the two dummy sense amplifiers 155-1 and 155-2 are generally configured in a manner similar to the output sense amplifiers 200, in the present embodiment they are more particularly configured to exhibit worst case reactions times based on known statistical variations of the sense amplifiers 200 over expected PVT ranges.

In a given read operation directed to the memory array 102, the self-time bitline 212 is precharged to a logic “1” level or VDD at the start of the operation. At a rising edge of the clock signal from clock latch 216, the self-time wordline signal transitions from a logic “0” level to a logic “1” level, which causes the self-time bitline 212 to start to discharge. The discharge of the self-time bitline causes the latch 210 to generate the SAEN signal which serves to turn on the output sense amplifiers 200. The SAEN signal is supplied to all of the output sense amplifiers and therefore experiences the horizontal RC delay previously described in conjunction with RC circuitry 220 of FIG. 2. This horizontal RC delay is addressed by feeding back the SAEN signal from a point after the last output sense amplifier 200-N to the control inputs of the dummy sense amplifiers 155-1 and 155-2, via the inverter 214 and feedback signal line 308.

As noted above, first sensing inputs 316 of each dummy sense amplifier 155 are coupled to the self-time bitline 212 via respective sets of pass gate circuitry P10-P12 and P13-P15, and second sensing inputs of each dummy sense amplifier 155 are connected to VDD. The above-noted transition in the self-time wordline turns off P10 and P13. The remaining pass gate circuitry serves to limit the differential voltages at respective sensing inputs 316-1 and 316-2 relative to VDD to levels that will accurately reflect the behavior of the output sense amplifiers 200. More particularly, the gates of transistors P11, P12, P14 and P15 are coupled together in a soft power zero arrangement, such that these transistors are always on, coupling self-time bitline 212 to each of the sensing inputs 316.

The transistor pairs P11-P12 and P14-P15 are configured such that across expected PVT variations the corresponding dummy sense amplifiers 155 will receive sufficient differential voltage between their two sensing inputs to trigger these sense amplifiers when turned on. This differential voltage is comparable to that received by the output sense amplifiers under similar conditions, and thus this circuitry arrangement serves to improve the ability of the reaction time tracking circuitry 310 to track the reaction time of the output sense amplifiers 200 to differential signals on their respective bitline pairs 120.

The PMOS pass gate transistors P11, P12, P14 and P15 in the FIG. 3 embodiment in one possible implementation have widths and lengths of about 0.4 and 0.06 micrometers, respectively, although other pass gate transistor dimensions could be used in other embodiments. These widths and lengths in this example may be on the order of about three times the respective minimum width and length in the corresponding process technology, which contributes to reducing the statistical variations, and ideally would contribute to minimize the statistical variations.

Other transistor dimensions in illustrative embodiments may include, for example, widths and lengths of about 0.4 and 0.03 micrometers, respectively, for the pass gate transistors of the dummy sense amplifiers 155-1 and 155-2. The pull-down transistors for all of the dummy and output sense amplifiers of the FIG. 3 embodiment may have widths and lengths of about 3.0 and 0.09 micrometers, respectively, and the pull-up transistors for all of these sense amplifiers may widths and lengths of about 0.5 and 0.08 micrometers, respectively. Again, other device dimensions may be used.

In other embodiments, the interconnection of the PMOS pass gate transistors P11, P12, P14 and P15 may be varied relative to the FIG. 3 arrangement in which the gates of these devices are all coupled together. For example, in one alternative arrangement, the gate of transistor P11 may be coupled to its drain and to the source of transistor P12, and the gate of transistor P14 may be coupled to its drain and to the source of transistor P15. In such an arrangement, gates of P12 and P15 may receive appropriate control signals.

When the dummy sense amplifiers 155-1 and 155-2 are turned on, their internal node pairs D and DN are disconnected from the corresponding sensing input lines 316 and 317, respectively, such that the DN nodes in both dummy sense amplifiers are pulled down to a logic “0” level. The DN nodes are used to generate the dummy sense amplifier outputs OUT1 and OUT2 in this embodiment. The dummy sense amplifier outputs OUT1 and OUT2 therefore both transition from a logic “0” level to a logic “1” level, causing the sense off signal at the output of NAND gate 312 to transition from a logic “1” level to a logic “0” level. This serves to reset the sense latch 210, via its active low reset input, causing SAEN to go to a logic “0” level, which turns off the output sense amplifiers 200, once again allowing their respective internal node pairs D-DN to precharge.

The sensing circuitry comprising reaction time tracking circuitry 310 with dummy sense amplifiers 155-1 and 155-2 as described above provides significantly improved tracking of output sense amplifier reaction time, thereby ensuring that the output sense amplifiers 200 are disabled in timely and efficient manner which properly takes into account the horizontal RC delay. This reduces read cycle time and improves the overall operating performance of the memory device 100.

It is to be appreciated that the particular sensing circuitry shown in the embodiments of FIGS. 2 and 3 is presented by way of illustration only, and a wide variety of other types of sensing circuitry may be utilized in other embodiments of the present invention. For example, in one or more of these other embodiments, the conductivity types of at least a subset of the PMOS and NMOS transistors of the sensing circuitry may be reversed, and other suitable modifications may be made to the circuitry and associated signaling levels, as would be appreciated by one skilled in the art. Also, other types of sensing circuitry and other memory device components may be used in implementing other embodiments.

Embodiments of the present invention are particularly well suited for use in high-speed SRAMs and DRAMs, as well as other types of memories that demand high read speeds, such as content-addressable memories (CAMs) and processor register files.

A given memory device configured in accordance with an embodiment of the present invention may be implemented as a stand-alone memory device, for example, as a packaged integrated circuit memory device suitable for incorporation into a higher-level circuit board or other system. Other types of implementations are possible, such as an embedded memory device, where the memory may be, for example, embedded into a processor or other type of integrated circuit device which comprises additional circuitry coupled to the memory device. More particularly, a memory device as described herein may comprise, for example, an embedded memory implemented within a microprocessor, digital signal processor (DSP), application-specific integrated circuit (ASIC), field-programmable gate array (FPGA) or other type of processor or integrated circuit device.

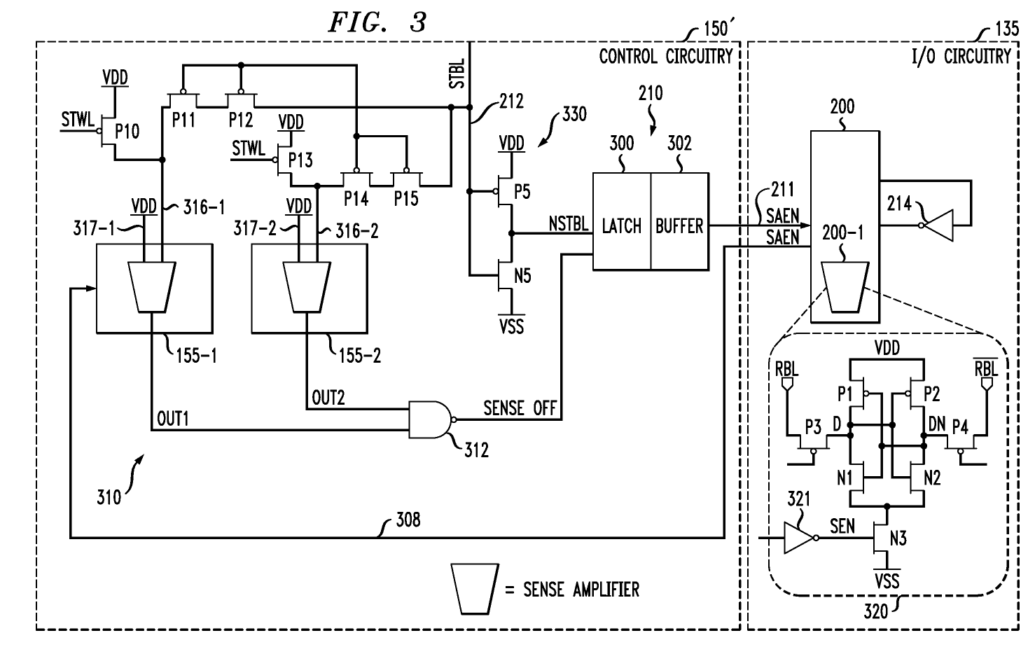

FIG. 4 shows an embodiment of a processing device 400 which incorporates the memory device 100 of FIG. 1. In this embodiment, the memory device 100 is coupled to a processor 402. The processing device further includes interface circuitry 404 coupled to the processor 402. The processing device 400 may comprise, for example, a computer, a server or a portable communication device such as a mobile telephone. The interface circuitry 404 may comprise one or more transceivers for allowing the device 400 to communicate over a network.

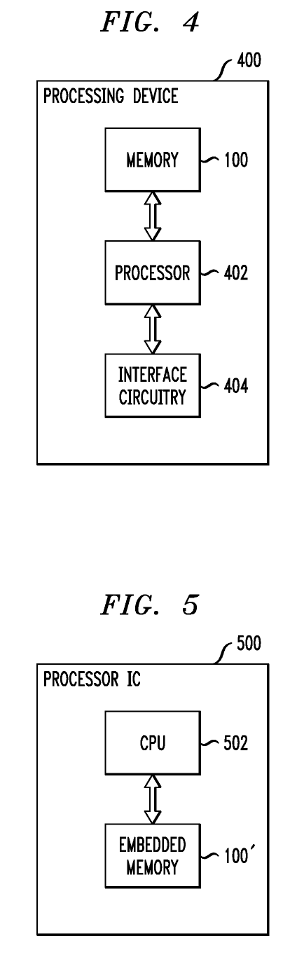

Alternatively, processing device 400 may comprise a microprocessor, DSP or ASIC, with processor 402 corresponding to a central processing unit (CPU) and memory device 100 providing at least a portion of an embedded memory of the microprocessor, DSP or ASIC. FIG. 5 shows an example of an arrangement of this type, with processor integrated circuit 500 incorporating the memory device of FIG. 1 as an embedded memory 100′. The embedded memory 100′ in this embodiment is coupled to a CPU 502. The embedded memory may comprise, for example, a high-speed register file. Numerous alternative embedded memory embodiments are possible.

As indicated above, embodiments of the invention may be implemented in the form of integrated circuits. In fabricating such integrated circuits, identical die are typically formed in a repeated pattern on a surface of a semiconductor wafer. Each die includes a memory device with sensing circuitry as described herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

Again, it should be emphasized that the above-described embodiments of the invention are intended to be illustrative only. For example, other embodiments can use different types and arrangements of memory arrays, memory cell circuitry, sense amplifier control circuitry, reaction time tracking circuitry, output and dummy sense amplifiers, transistor conductivity types, control signals, and other elements for implementing the described functionality. These and numerous other alternative embodiments within the scope of the following claims will be apparent to those skilled in the art.

What is claimed is:

1. A memory device comprising:
a memory array comprising a plurality of memory cells arranged in rows and columns; and
sensing circuitry coupled to the memory array;
the sensing circuitry comprising:
a plurality of output sense amplifiers configured to sense stored data associated with respective columns of the memory array; and
sense amplifier control circuitry configured to generate a sense amplifier control signal for application to control inputs of respective ones of the output sense amplifiers;
the sense amplifier control circuitry comprising reaction time tracking circuitry including at least one dummy sense amplifier configured to track reaction time of one or more of the output sense amplifiers;
wherein the sense amplifier control signal is generated at least in part responsive to an output signal of the dummy sense amplifier.

2. The memory device of claim 1 wherein the sense amplifier control signal comprises a sense amplifier enable signal.

3. The memory device of claim 1 wherein the output signal of the dummy sense amplifier comprises a sense off signal.

4. The memory device of claim 1 wherein the sense amplifier control circuitry further comprises a sense latch having a reset input coupled to an output of the dummy sense amplifier and an output coupled to the control inputs of the output sense amplifiers.

5. The memory device of claim 4 further comprising a dummy column having a self-time bitline, and wherein a set input of the sense latch and a data input of the dummy sense amplifier are both coupled to the self-time bitline of the dummy column.

6. The memory device of claim 5 wherein the set input of the sense latch is coupled to the self-time bitline via an inverter.

7. The memory device of claim 5 wherein the dummy sense amplifier is configured for sensing of the self-time bitline by coupling of a first internal node of the dummy sense amplifier to the self-time bitline via at least one pass gate transistor and coupling of a second internal node of the dummy sense amplifier to an upper voltage supply line, wherein said at least one pass gate transistor is configured to ensure that a minimum differential voltage will appear between the first and second internal nodes of the dummy sense amplifier at a time when said dummy sense amplifier is enabled.

8. The memory device of claim 1 wherein the dummy sense amplifier has a control input adapted to receive a feedback signal generated from the sense amplifier control signal applied to the control inputs of the output sense amplifiers.

9. The memory device of claim 8 further comprising an inverter having an input adapted to receive the sense amplifier control signal and an output providing the feedback signal for application to the control input of the dummy sense amplifier.

10. The memory device of claim 1 wherein the reaction time tracking circuitry comprises a plurality of dummy sense amplifiers, each configured to track reaction time of one or more of the output sense amplifiers, and logic circuitry adapted to process output signals from respective ones of the dummy sense amplifiers to generate a sense off signal for application to a reset input of a sense latch of the sense amplifier control circuitry.

11. The memory device of claim 10 wherein the logic circuitry comprises a NAND gate having first and second inputs adapted to receive first and second output signals from first and second ones of the dummy sense amplifiers, respectively, and an output providing the sense off signal for application to the reset input of the sense latch.

12. The memory device of claim 1 wherein a given one of the sense amplifiers comprises a differential sense amplifier having a sensing element with first and second internal nodes and at least one pair of cross-coupled transistors having their gates coupled to respective ones of the first and second internal nodes.

13. The memory device of claim 12 wherein the sensing element comprises:
a first pair of cross-coupled transistors of a first conductivity type with their gates coupled to respective ones of the first and second internal nodes;
a second pair of cross-coupled transistors of a second conductivity type with their gates coupled to respective ones of the first and second internal nodes; and
switching circuitry configured to enable and disable the sensing element responsive to respective logic levels of the sense amplifier control signal.

14. The memory device of claim 13 wherein the first pair of cross-coupled transistors comprises first and second p-type field effect transistors, with the first p-type field effect transistor having its gate coupled to the second internal node, its source coupled to an upper voltage supply line, and its drain coupled to the first internal node, and with the second p-type field effect transistor having its gate coupled to the first internal node, its source coupled to the upper voltage supply line, and its drain coupled to the second internal node.

15. The memory device of claim 13 wherein the second pair of cross-coupled transistors comprises first and second n-type field effect transistors, with the first n-type field effect transistor having its gate coupled to the second internal node, its source coupled to a lower voltage supply line via the control circuitry, and its drain coupled to the first internal node, and with the second n-type field effect transistor having its gate coupled to the first internal node, its source coupled to the lower voltage supply line via the control circuitry, and its drain coupled to the second internal node.

16. The memory device of claim 13 wherein the switching circuitry comprises a field effect transistor having its gate adapted to receive the sense amplifier control signal, one of its source and drain coupled to a voltage supply line and the other of its source and drain coupled to source or drain terminals of one of the pairs of cross-coupled transistors.

17. An integrated circuit comprising the memory device of claim 1.

18. A processing device comprising the memory device of claim 1.

19. A method comprising:
tracking reaction time of an output sense amplifier of a memory device in at least one dummy sense amplifier of that memory device; and
generating a sense amplifier control signal for controlling the output sense amplifier at least in part responsive to an output signal of the dummy sense amplifier.

20. The method of claim 19 wherein the step of generating a sense amplifier control signal further comprises processing output signals from a plurality of dummy sense amplifiers, each configured to track reaction time of the output sense amplifier, to generate a sense off signal for application to a reset input of a sense latch that provides the sense amplifier control signal at an output thereof.
